(19) United States
(12) Patent Application Publication
(10) Pub. No.: US 2021/0358833 A1
(43) Pub. Date: Nov. 18, 2021

(54) DIRECT COOLING POWER SEMICONDUCTOR PACKAGE

(71) Applicant: Lite-On Semiconductor Corporation, Hsinchu City (TW)

(72) Inventors: Chung Hsing Tzu, Hsinchu City (TW); Meng-Hsun Tu, Hsinchu City (TW)

(73) Assignee: Lite-On Semiconductor Corporation, Hsinchu City (TW)

(21) Appl. No.: 17/009,762

(22) Filed: Sep. 1, 2020

Related U.S. Application Data
(60) Provisional application No. 63/025,167, filed on May 14, 2020.

(51) Int. Cl. H01L 23/467; H01L 23/473

(52) U.S. Cl. CPC H01L 23/467; H01L 23/473

(57) ABSTRACT

A direct cooling power semiconductor package includes a power package and a cooling structure. The power package includes at least a power device on a first surface of a substrate, and the cooling structure is disposed on a second surface of the substrate, wherein the second surface and the first surface are opposite to each other, and the cooling structure includes a housing covering the second surface to form a containing space, a cooling liquid fluid or gas filled in the containing space, and a plurality of semi-closed metal structures. The semi-closed metal structures are in direct contact with the second surface in the housing.

### CROSS-REFERENCE TO RELATED APPLICATION

This application claims the priority benefit of U.S. provisional application Ser. No. 63/025,167, filed on May 14, 2020. The entirety of the above-mentioned patent application is hereby incorporated by reference herein and made a part of this specification.

### BACKGROUND

### Technical Field

The disclosure relates to a power semiconductor package, and particularly relates to a direct cooling power semiconductor package.

### Description of Related Art

The power semiconductor device generates high amount of heat during operation, the heat dissipation is thus one of the main issues to be improved.

Recently, heat sink with coolant is widely applied in the cooling elements in the power semiconductor package. For example, the heat sink is usually made in the form of pin-like.

However, there is still room for improvement in heat dissipation efficiency, specifically in terms of the heat accumulation due to poor rheology of the coolant.

### SUMMARY

The disclosure provides a direct cooling power semiconductor package which is excellent in heat dissipation efficiency.

The direct cooling power semiconductor package of the disclosure includes a power package comprising at least one power device on a first surface of a substrate, and a cooling structure. The substrate has a first surface and a second surface opposite to each other, and the cooling structure is disposed on the second surface of the substrate. The cooling structure includes a housing covering the second surface to form a containing space, a cooling liquid fluid or gas filled in the containing space, and semi-closed metal structures which are in direct contact with the second surface in the housing.

In an embodiment of the disclosure, the semi-closed metal structures are orderly distributed.

In an embodiment of the disclosure, the semi-closed metal structures are separated from each other by a gap.

In an embodiment of the disclosure, every N of the semi-closed metal structures forms a sub-structure, wherein N is odd.

In an embodiment of the disclosure, the sub-structure is a multi-layered structure.

In an embodiment of the disclosure, the semi-closed metal structures are trigonal structures, tetragonal structures, hexagonal structures, or a combination thereof.

In an embodiment of the disclosure, the semi-closed metal structures are hexagonal structures, each of the semi-closed metal structures consists of six sheets, and each sheets has an inner surface, an outer surface, and two opposite edges between the inner surface and the outer surface.

In an embodiment of the disclosure, the outer surface of one of the six sheets is in direct contact with the second surface.

In an embodiment of the disclosure, the length of each of the two opposite edges is 8-10 mm.

In an embodiment of the disclosure, the width of each of the six sheets is 1-5 mm.

In an embodiment of the disclosure, the thickness of each of the six sheets is 1-5 mm.

In an embodiment of the disclosure, the height of each of the semi-closed metal structures is 5-8 mm.

In an embodiment of the disclosure, each of the semi-closed metal structures is the same in size or shape.

In an embodiment of the disclosure, each of the semi-closed metal structures is different in size or shape.

In an embodiment of the disclosure, the semi-closed metal structures are connected to form a net structure.

In an embodiment of the disclosure, the substrate comprises a metal plate or a metal laminated substrate.

In an embodiment of the disclosure, the metal laminated substrate comprises an insulated metal substrate (IMS) or a direct bonded copper substrate (DBC).

In an embodiment of the disclosure, the direct cooling power semiconductor package further comprises another substrate disposed on a surface of the power package opposite to the cooling structure, and another cooling structure disposed on the another substrate opposite to the power package.

In an embodiment of the disclosure, the another cooling structure is the same as the cooling structure disposed on the second surface of the substrate.

Based on the above, since the disclosure provides a specific cooling structure, it can improve the rheology of cooling liquid flow so as to optimize the heat dissipation with low cost.

The specific cooling structure according to the disclosure could also be utilized in the form of double sided cooling. Specifically, the semi-closed metal structures of the cooling structure are arranged, in its configuration and/or size, to provide a Tj (junction temperature) of lower than 150° C.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1A is a schematic top view of a direct cooling power semiconductor package according to a first embodiment of the disclosure.

FIG. 1B is a schematic side view of the direct cooling power semiconductor package of FIG. 1A.

FIG. 2A shows a three-dimensional view of one semi-closed metal structure of the direct cooling power semiconductor package of FIG. 1A.

FIG. 2B shows a three-dimensional view of another semi-closed metal structure of the direct cooling power semiconductor package according to the first embodiment of the disclosure.

FIG. 2C shows a three-dimensional view of yet another semi-closed metal structure of the direct cooling power semiconductor package according to the first embodiment of the disclosure.

FIG. 3 is a schematic side view of a direct cooling power semiconductor package according to a second embodiment of the disclosure.

FIG. 4 is a schematic side view of a direct cooling power semiconductor package according to a third embodiment of the disclosure.

FIG. 5 is a schematic side view of a direct cooling power semiconductor package according to a fourth embodiment of the disclosure.

FIG. 6 is a schematic side view of a direct cooling power semiconductor package according to a fifth embodiment of the disclosure.

FIG. 7 is a schematic top view of a direct cooling power semiconductor package according to a sixth embodiment of the disclosure.

FIG. 8 is a schematic side view of a direct cooling power semiconductor package according to a seventh embodiment of the disclosure.

### DESCRIPTION OF THE EMBODIMENTS

Referring to the embodiments below and the accompanied drawings for a sufficient understanding of the disclosure. However, the disclosure may be implemented in many other different forms and should not be construed as limited to the embodiments described hereinafter. In the drawings, for clarity, the elements and relative dimensions thereof may not be scaled. For easy understanding, the same elements in the following embodiments will be denoted by the same reference numerals.

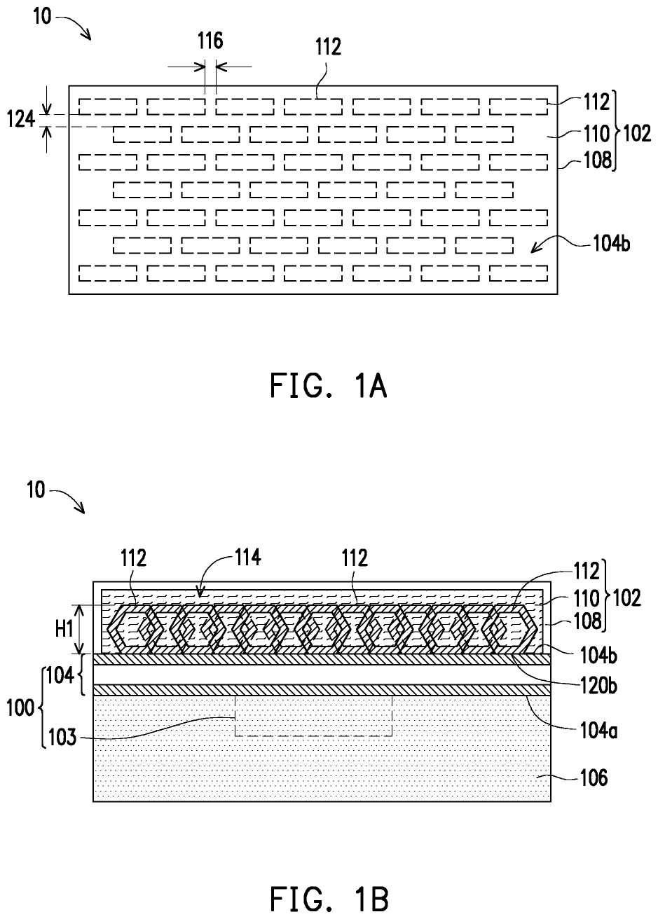

FIG. 1A is a schematic top view of a direct cooling power semiconductor package according to a first embodiment of the disclosure. FIG. 1B is a schematic side view of the direct cooling power semiconductor package of FIG. 1A.

Referring to FIGS. 1A and 1B, the direct cooling power semiconductor package 10 of the first embodiment includes a power package 100 and a cooling structure 102. The power package 100 includes at least one power device 103 on a first surface 104a of a substrate 104, wherein the substrate 104 may be a metal plate or a metal laminated substrate such as an insulated metal substrate (IMS). In one embodiment, the power device 103 may be covered by a molding compound 106. The cooling structure 102 is disposed on a second surface 104b of the substrate 104, wherein the first surface 104a and the second surface 104b are opposite to each other. The cooling structure 102 includes a housing 108, a cooling liquid fluid or gas 110, and semi-closed metal structures 112. The housing 108 covers the second surface 104b to form a containing space 114, the cooling liquid fluid or gas 110 is filled in the containing space 114, and the semi-closed metal structures 112 are in direct contact with the second surface 104b in the housing 108. Herein, the so-called “semi-closed” structure represents a structure closed in two-dimensional plane and open in one direction; for example, a structure closed in X-Y plane and open in Z direction. A material of the semi-closed metal structures 112 is, for example, copper. The semi-closed metal structures 112 may be trigonal structures, tetragonal structures, hexagonal structures, or a combination thereof. The semi-closed metal structures 112 can be bonded on the metal surface (such as second surface 104b) of the power package 100 by 3D printing or metal adhesive or thermal conductive layer. In the first embodiment, the semi-closed metal structures 112 are preferably hexagonal structures. The hexagonal structure is more advantageous than other shapes (such as trigonal or tetragonal structure) for trapping the coolant within the cooling structure, especially in the case that the semi-closed metal structures 112 of the cooling structure 102 are staggered along the X and Y direction. Moreover, the hexagonal structures can be connected and stacked with each other to form a continuous connected structure, in comparison with other shapes, the continuous connected structure is more stable stacked structure with closest arrangement, so that the heat dissipation capacity can be greatly increased. In one embodiment, the semi-closed metal structures 112 are orderly distributed and separated from each other by a gap 116, wherein each of the semi-closed metal structures 112 is the same in size or shape. However, the disclosure is not limited to orderly distributed (including orientation and arrangement), and the arrangement and orientation of the semi-closed metal structures 112 can also be changed to adjust rheology appropriately. In addition, the size or shape of each of the semi-closed metal structures 112 can be changed based on desired needs.

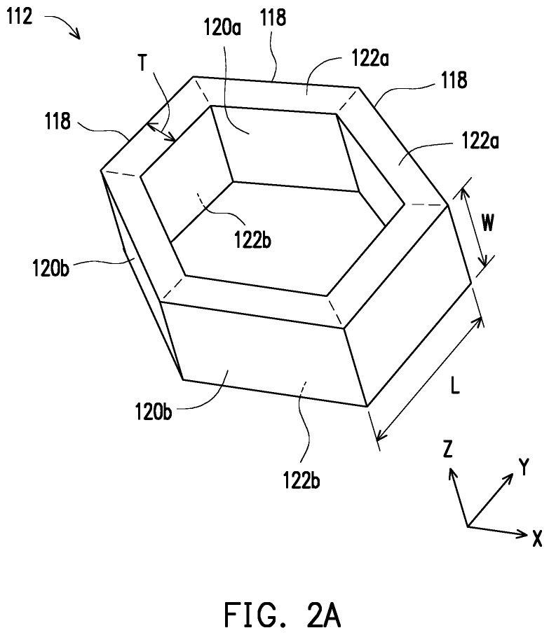

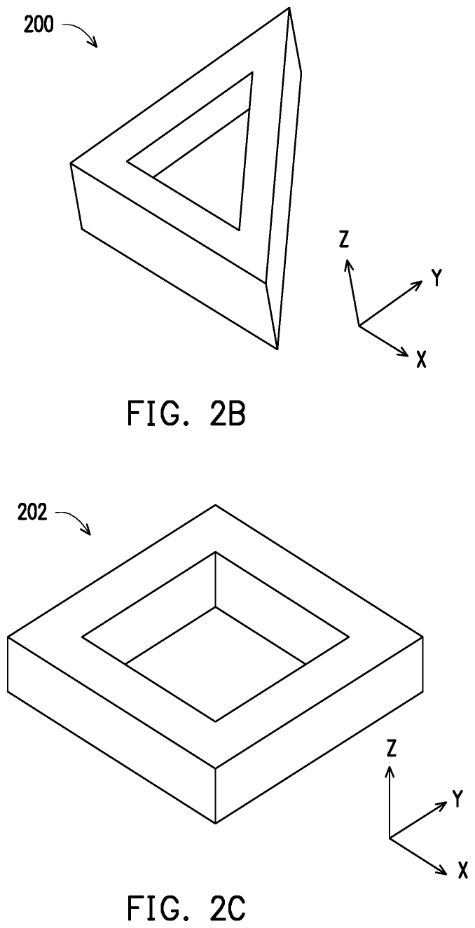

FIG. 2A shows a three-dimensional view of one semi-closed metal structure 112 of the direct cooling power semiconductor package of FIG. 1A. Each of the semi-closed metal structures 112 is a hexagonal structure, and it may consist of six sheets 118. Each sheets 118 has an inner surface 120a, an outer surface 120b, and two opposite edges 122a and 122b between the inner surface 120a and the outer surface 120b. In the first embodiment, the outer surface 120b of one of the six sheets 118 is in direct contact with the second surface 104b as shown FIG. 1B. The size of each of the semi-closed metal structures 112 can be proportional to the size of the power package 100; i.e. the larger the size of the power package 100 is, the thicker the thickness T of each sheets 118 is. For example, the length L of each of the two opposite edges 122a and 122b is 8-10 mm, the width W of each sheets 118 is 1-5 mm, the thickness T of each sheets 118 is 1-5 mm, and the height H1 of each of the semi-closed metal structures 112 is 5-8 mm. In the first embodiment, both the distance of the gap 116 and row distance 124 in FIG. 1A are not greater than the length L.

FIGS. 2B and 2C show two three-dimensional views of another semi-closed metal structures of the direct cooling power semiconductor package according to the first embodiment of the disclosure. In FIG. 2B, the semi-closed metal structure 200 is a trigonal structure. In FIG. 2C, the semi-closed metal structure 202 is a tetragonal structure.

In the first embodiment, the semi-closed metal structures 112 of the cooling structure 102 are attached on the substrate 104 of the power package 100 and exposed to the cooling liquid fluid or gas 110, and thus the rheology of the cooling flow can be improved to optimize the heat dissipation.

FIG. 3 is a schematic side view of a direct cooling power semiconductor package according to a second embodiment of the disclosure, wherein the reference symbols used in the first embodiment are used to equally represent the same or similar devices. The description of the same components can be derived from the first embodiment, and will not be repeated here.

Referring to FIG. 3, the direct cooling power semiconductor package 30 of the second embodiment includes a power package 300 and a cooling structure 102. The power package 300 includes at least one power device 103 on a first surface 302a of a substrate 302, wherein the substrate 302 is a metal laminated substrate such as a direct bonded copper substrate (DBC), and a metal layer 304 is formed between the DBC and the cooling structure 102 to be beneficial to attach the semi-closed metal structures 112 on the substrate 302, wherein the metal layer 304 may be made of nickel (Ni) or aluminum (Al) for example. In the second embodiment, if the semi-closed metal structure 112 is a hexagonal structure, both the gap distance and the row distance of the semi-closed metal structures 112 are not greater than the edge length of the hexagonal structure.

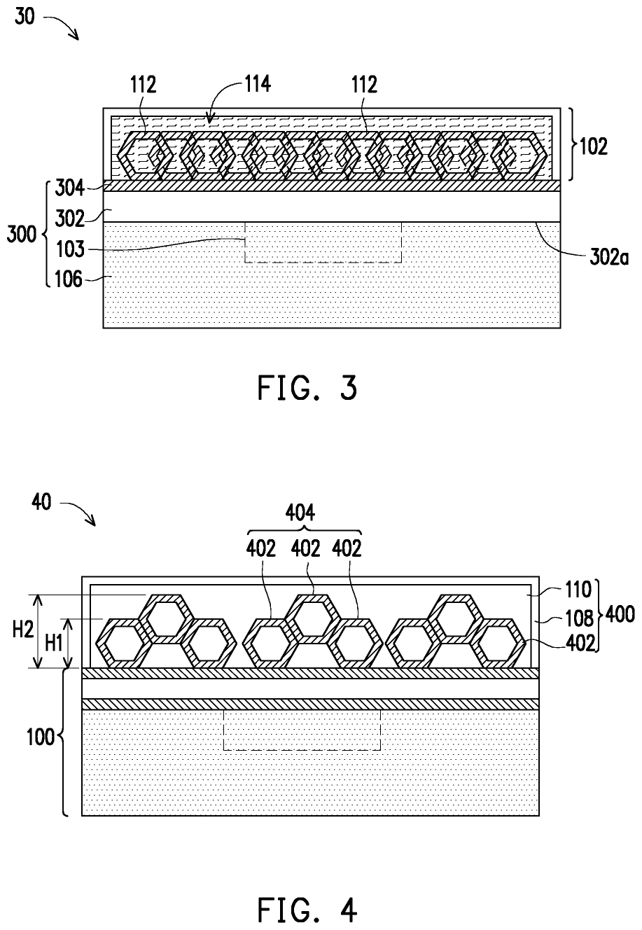

FIG. 4 is a schematic side view of a direct cooling power semiconductor package according to a third embodiment of the disclosure, wherein the reference symbols used in the first embodiment are used to equally represent the same or similar devices. The description of the same components can be derived from the first embodiment, and will not be repeated here.

Referring to FIG. 4, the direct cooling power semiconductor package 40 of the third embodiment includes a power package 100 and a cooling structure 400. The cooling structure 400 includes a housing 108, a cooling gas 110, and semi-closed metal structures 402, wherein every N of the semi-closed metal structures 402 forms a sub-structure 404, and N is odd (e.g. three in FIG. 4). However, the disclosure is not limited thereto. The N may be 5, 7, 9, and so on. In one embodiment, the height H2 of each of the sub-structure 404 may be 8-12 mm if the height H1 of each of the semi-closed metal structures 402 is 5-8 mm. In other words, the semi-closed metal structures 402 in each of the sub-structure 404 may be connected each other in one direction (such as a length direction of the power package 100), and the sub-structures 404 may be separated, wherein the sub-structure 404 is a multi-layered structure including two-layered semi-closed metal structures 402, but the disclosure is not limited thereto. If the sub-structure 404 is extended to an almost whole length of the power package 100, the sub-structure 404 can be regarded as the continuous connected structure. In the third embodiment, if the semi-closed metal structure 402 is a hexagonal structure, both the gap distance and the row distance of the sub-structures 404 are not greater than the edge length of the hexagonal structure.

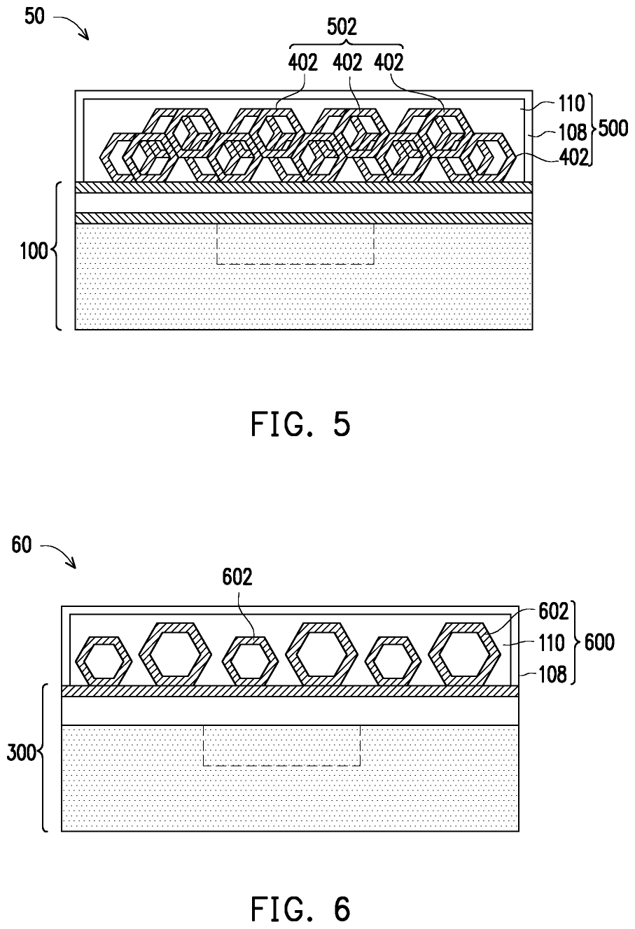

FIG. 5 is a schematic side view of a direct cooling power semiconductor package according to a fourth embodiment of the disclosure, wherein the reference symbols used in the third embodiment are used to equally represent the same or similar devices. The description of the same components can be derived from the third embodiment, and will not be repeated here.

Referring to FIG. 5, the direct cooling power semiconductor package 50 of the fourth embodiment includes a power package 100 and a cooling structure 500. Every nine of the semi-closed metal structures 402 forms a sub-structure 502 in the cooling structure 500. In the fourth embodiment, the sub-structure 502 is extended to an almost whole length of the power package 100, so the sub-structure 502 can be regarded as a continuous connected structure. In the fourth embodiment, adjacent sub-structures 502 on the power package 100 are in a staggered arrangement. In the fourth embodiment, if the semi-closed metal structure 402 is a hexagonal structure, both the gap distance and the row distance of the sub-structures 502 are not greater than the edge length of the hexagonal structure.

FIG. 6 is a schematic side view of a direct cooling power semiconductor package according to a fifth embodiment of the disclosure, wherein the reference symbols used in the second embodiment are used to equally represent the same or similar devices. The description of the same components can be derived from the second embodiment, and will not be repeated here.

Referring to FIG. 6, the direct cooling power semiconductor package 60 of the fifth embodiment includes a power package 300 and a cooling structure 600. The cooling structure 600 includes a housing 108, a cooling liquid fluid or gas 110, and semi-closed metal structures 602. Each of the semi-closed metal structures 602 is different in size or shape. For clarify, only one row of the semi-closed metal structures 602 is shown in FIG. 6, but it should be known that the cooling structure 600 may comprise multiple rows of the semi-closed metal structures 602. In the fifth embodiment, some of the semi-closed metal structures 602 have the same size, but others have different sizes. In the fifth embodiment, the semi-closed metal structures 602 are hexagonal structures, and both the gap distance and the row distance of the semi-closed metal structures 602 are not greater than the edge length of the hexagonal structure. In another embodiment, the semi-closed metal structures 602 may be trigonal structures, tetragonal structures or a combination of the hexagonal structures and above structures.

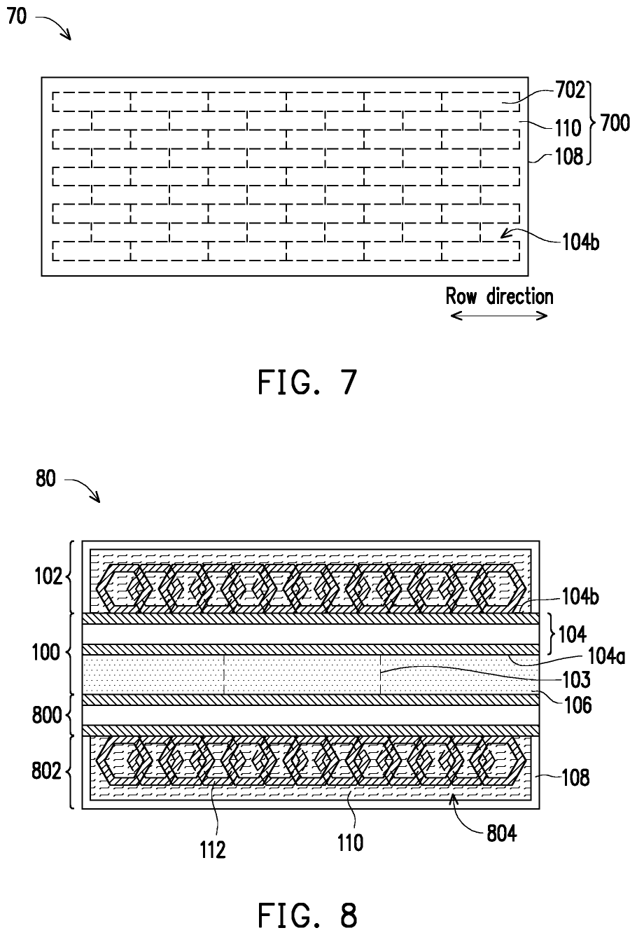

FIG. 7 is a schematic top view of a direct cooling power semiconductor package according to a sixth embodiment of the disclosure, wherein the reference symbols used in the first embodiment are used to equally represent the same or similar devices. The description of the same components can be derived from the first embodiment, and will not be repeated here.

Referring to FIG. 7, the direct cooling power semiconductor package 70 of the sixth embodiment includes a power package (100 in FIG. 1B) and a cooling structure 700. The cooling structure 700 includes semi-closed metal structures 702 in the housing 108. In the sixth embodiment, the semi-closed metal structures 702 may be trigonal structures, tetragonal structures, hexagonal structures, or a combination thereof. The semi-closed metal structures 702 are connected to form a net structure, wherein any two adjacent semi-closed metal structures 702 in row direction are staggered for the rheology of the cooling flow.

FIG. 8 is a schematic side view of a direct cooling power semiconductor package according to a seventh embodiment of the disclosure, wherein the reference symbols used in the first embodiment are used to equally represent the same or similar devices. The description of the same components can be derived from the first embodiment, and will not be repeated here.

Referring to FIG. 8, the direct cooling power semiconductor package 80 of the seventh embodiment includes a power package 100, a cooling structure 102, another substrate 800, and another cooling structure 802. The cooling structure 102 is disposed on the second surface 104b of the substrate 104, and the power package 100 is disposed on the first surface 104a of the substrate 104. The substrate 800 is disposed on the surface of the power package 100 opposite to the cooling structure 102. The cooling structure 802 is disposed on the substrate 800 opposite to the power package 100. In one embodiment, the another cooling structure 802 is the same as the cooling structure 102. That is, The cooling structure 802 includes a housing 108, a cooling liquid fluid or gas 110, and semi-closed metal structures 112. The housing 108 covers the substrate 800 to form a containing space 804, the cooling liquid fluid or gas 110 is filled in the containing space 804, and the semi-closed metal structures 112 are in direct contact with the substrate 800 in the housing 108. However, the disclosure is not limited thereto. The cooling structure 802 may be replaced by any one of the cooling structure according to above embodiments.

In summary, the direct cooling power semiconductor package according to the disclosure can improve the rheology of cooling liquid flow through specific cooling structure bonded on the power package, and thus it can achieve in low cost and high heat dissipation.

Compared with the traditional pin fin, the semi-closed structures are beneficial to conduct heat away from the heat source so as to avoid heat accumulation at the near-heat source end of the cooling structure. In addition, the semi-closed structure is more effective in trapping coolant within the cooling structure for longer period, and in reducing the formation of stationary flow. Accordingly, the semi-closed structure according to the disclosure can greatly increase the efficiency of heat dissipation. Specifically, the semi-closed metal structures of the cooling structure are arranged, in its configuration and/or size, to provide low Tj (junction temperature).

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A direct cooling power semiconductor package, comprising:
a power package comprising at least one power device on a first surface of a substrate; and
a cooling structure, disposed on a second surface of the substrate, wherein the second surface and the first surface are opposite to each other, and the cooling structure comprises a housing covering the second surface to form a containing space, a cooling liquid fluid or gas filled in the containing space, and a plurality of semi-closed metal structures which is in direct contact with the second surface in the housing.

2. The direct cooling power semiconductor package according to claim 1, wherein the semi-closed metal structures are orderly distributed.

3. The direct cooling power semiconductor package according to claim 1, wherein the semi-closed metal structures are separated from each other by a gap.

4. The direct cooling power semiconductor package according to claim 1, wherein every N of the semi-closed metal structures forms a sub-structure, and N is odd.

5. The direct cooling power semiconductor package according to claim 4, wherein the sub-structure comprises a multi-layered structure.

6. The direct cooling power semiconductor package according to claim 1, wherein the semi-closed metal structures are trigonal structures, tetragonal structures, hexagonal structures, or a combination thereof.

7. The direct cooling power semiconductor package according to claim 1, wherein the semi-closed metal structures are hexagonal structures, each of the semi-closed metal structures consists of six sheets, and each sheets has an inner surface, an outer surface, and two opposite edges between the inner surface and the outer surface.

8. The direct cooling power semiconductor package according to claim 7, wherein the outer surface of one of the six sheets is in direct contact with the second surface.

9. The direct cooling power semiconductor package according to claim 7, wherein a length of each of the two opposite edges is 8-10 mm.

10. The direct cooling power semiconductor package according to claim 7, wherein a width of each of the six sheets is 1-5 mm.

11. The direct cooling power semiconductor package according to claim 7, wherein a thickness of each of the six sheets is 1-5 mm.

12. The direct cooling power semiconductor package according to claim 7, wherein a height of each of the semi-closed metal structures is 5-8 mm.

13. The direct cooling power semiconductor package according to claim 1, wherein each of the semi-closed metal structures is the same in size or shape.

14. The direct cooling power semiconductor package according to claim 1, wherein each of the semi-closed metal structures is different in size or shape.

15. The direct cooling power semiconductor package according to claim 1, wherein the semi-closed metal structures are connected to form a net structure.

16. The direct cooling power semiconductor package according to claim 1, wherein the substrate comprises a metal plate or a metal laminated substrate.

17. The direct cooling power semiconductor package according to claim 16, wherein the metal laminated substrate comprises an insulated metal substrate (IMS) or a direct bonded copper substrate (DBC).

18. The direct cooling power semiconductor package according to claim 1, further comprising:
another substrate, disposed on a surface of the power package opposite to the cooling structure; and
another cooling structure, disposed on the another substrate opposite to the power package.

19. The direct cooling power semiconductor package according to claim 18, wherein the another cooling structure is the same as the cooling structure disposed on the second surface of the substrate.
